(19) United States
(12) Patent Application Publication
(10) Pub. No.: US 2013/0186679 A1
(43) Pub. Date: Jul. 25, 2013

(54) MULTILAYER WIRING STRUCTURE AND METHOD OF MANUFACTURING THE SAME

(71) Applicant: SAMSUNG ELECTRO-MECHANICS CO., LTD., Suwon (KR)

(72) Inventors: Jin Uk Lee, Suwon (KR); Woo Jin Lee, Suwon (KR); Dong Hwan Lee, Suwon (KR)

(73) Assignee: SAMSUNG ELECTRO-MECHANICS CO., LTD., Suwon (KR)

(21) Appl. No.: 13/735,813

(22) Filed: Jan. 7, 2013

(30) Foreign Application Priority Data
Jan. 19, 2012 (KR) 10-2012-0006147

(51) Int. Cl. H05K 3/40; H05K 1/11

(52) U.S. Cl. CPC H05K 3/4038; H05K 1/115
USPC 174/262; 216/13; 427/96.9

(57) ABSTRACT

The multilayer wiring structure includes: a substrate; a connection hole formed to pass through one surface and another surface of the substrate; and electrode wirings formed on the substrate, wherein the electrode wirings includes: a plurality of first wirings formed on one surface of the substrate; a plurality of second wirings formed on another surface of the substrate; and a plurality of connection wirings formed on an inner surface of the connection hole and electrically connecting the plurality of first wirings and the plurality of second wirings, respectively.

### CROSS REFERENCE TO RELATED APPLICATION

This application claims the benefit of Korean Patent Application No. 10-2012-0006147, filed on Jan. 19, 2012, entitled “Wiring Structure and the Manufacturing Method”, which is hereby incorporated by reference in its entirety into this application.

### BACKGROUND OF THE INVENTION

1. Technical Field

The present invention relates to a multilayer wiring structure and a method of manufacturing the multilayer wiring structure.

2. Description of the Related Art

In general, a substrate is coating of a copper foil on an epoxy based insulation substrate, and its types may be classified as a cross-section printed circuit board (PCB) and a multilayer circuit board. The substrate may further include a touch substrate formed of a transparent material.

In this regard, the PCB has a structure in which a copper foil in a wiring pattern is coated on both sides of an insulation substrate and a connection hole that passes through both sides of the insulation substrate is formed.

At this time, the wiring patterns formed in both sides of the insulation substrate are connected through a connection hole while one connection hole is formed for each wiring pattern.

Therefore, a plurality of connection holes are formed when a plurality of wiring patterns are formed, and thus space is limited, and concentration is low.

Furthermore, when a drilling operation is used to form a plurality of connection holes, drills are frequently exchanged due to abrasion of a drill, which increases an operation time and incurs enormous exchange expense.

### SUMMARY OF THE INVENTION

The present invention has been made in an effort to provide a multilayer wiring structure that connects a plurality of wirings formed on a substrate in a plurality of layers through a single connection hole and a method of manufacturing the multilayer wiring structure.

According to a first preferred embodiment of the present invention, there is provided a multilayer wiring structure including: a substrate; a connection hole formed to pass through one surface and another surface of the substrate; and electrode wirings formed on the substrate, wherein the electrode wirings include: a plurality of first wirings formed on one surface of the substrate; a plurality of second wirings formed on another surface of the substrate; and a plurality of connection wirings formed on an inner surface of the connection hole and electrically connecting the plurality of first wirings and the plurality of second wirings, respectively.

The plurality of first wirings and the plurality of second wirings may be arranged to be in disagreement with each other.

According to a second preferred embodiment of the present invention, there is provided a method of manufacturing a multilayer wiring structure, the method including: a hole forming operation of forming a connection hole through which one surface and another surface of a substrate pass; a metal layer forming operation of plating a metal layer on one surface and another surface of the substrate and an inner surface of the connection hole; a resist stacking operation of stacking patterned first resist and second resist on the metal layer formed in both sides of the substrate respectively; and an electrode wirings forming operation of forming the patterned electrode wirings by etching or plating the metal layer through the first resist and the second resist.

The electrode wirings may include: a first wiring formed on one surface of the substrate; a second wiring formed on another surface of the substrate; and a connection wiring formed on an inner surface of the connection hole.

The method may further include: after the patterning operation, a resist removing operation of separating the first resist and the second resist.

In the resist stacking operation, the first resist and the second resist may be patterned and formed to be in disagreement with each other.

In the resist stacking operation, the first resist may be formed of a dry film, and the second resist may be a liquid resist, so that the connection hole may be filled with the liquid resist.

The resist stacking operation may include: a resist forming operation of forming the first resist on one surface of the substrate and the second resist on another surface of the substrate; a curing operation of selectively curing the dry film and the liquid resist by selectively exposing the first resist and the second resist through patterned photomasks; and removing operation of removing parts of the first resist and the second resist that are not cured by using a developing liquid.

In the resist forming operation, the first resist may be formed of a dry film and coated on one surface of the substrate, and the second resist may be a liquid resist and coated on another surface of the substrate.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view of a multilayer wiring structure according to an embodiment of the present invention;

FIG. 2 is a cut perspective view of a multilayer wiring structure according to an embodiment of the present invention;

FIG. 3 is a perspective view of electrode wirings of a multilayer wiring structure according to an embodiment of the present invention;

FIG. 4 is a flowchart of a method of manufacturing a multilayer wiring structure according to another embodiment of the present invention;

FIG. 5 is a perspective view of a multilayer wiring structure manufactured by using a method of manufacturing the multilayer wiring structure according to another embodiment of the present invention;

FIG. 6 is an exploded perspective view of a multilayer wiring structure manufactured by using a method of manufacturing the multilayer wiring structure according to another embodiment of the present invention;

FIGS. 7 through 12 are sequentially cross-sectional views taken from a line A-A′ of FIG. 5 in a method of manufacturing the multilayer wiring structure according to another embodiment of the present invention;

FIGS. 13 through 17 are sequentially cross-sectional views taken from a line B-B′ of FIG. 5 in a method of manufacturing the multilayer wiring structure according to another embodiment of the present invention; and

FIG. 18 is a perspective view of a main part of electrode wirings of a multilayer wiring structure and a method of manufacturing the multilayer wiring structure according to an embodiment and another embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

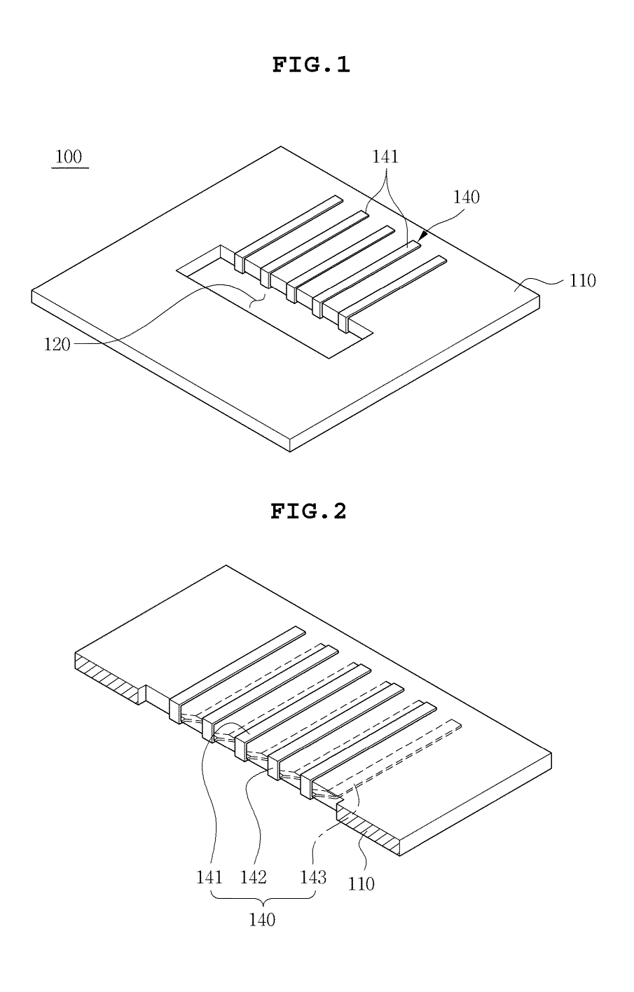

FIG. 1 is a perspective view of a multilayer wiring structure 100 according to an embodiment of the present invention.

Referring to FIG. 1, the multilayer wiring structure 100 includes a substrate 110, a connection hole 120 formed in the substrate 110, and an electrode wiring 140 formed in the substrate 110.

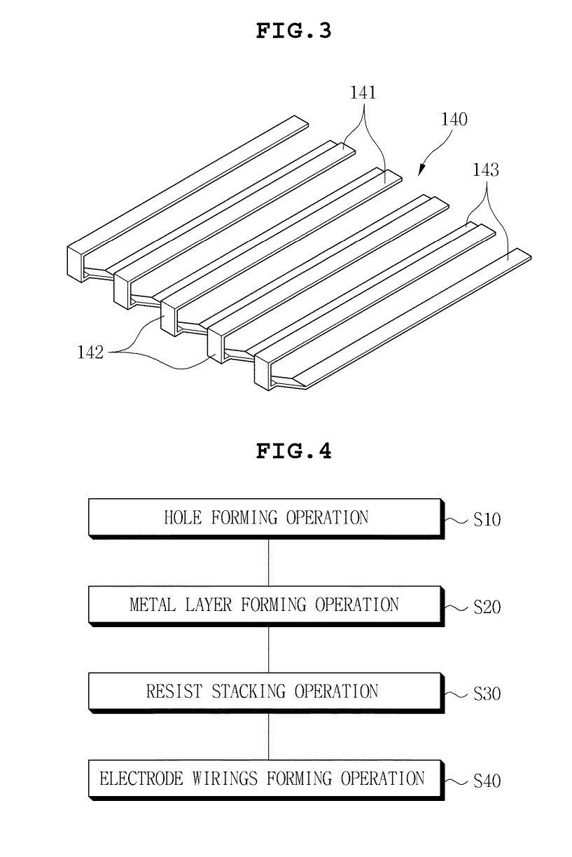

FIG. 2 is a cut perspective view of a multilayer wiring structure according to an embodiment of the present invention. FIG. 3 is a perspective view of electrode wirings of a multilayer wiring structure according to an embodiment of the present invention.

The multilayer wiring structure according to an embodiment of the present invention will now be described in more detail with reference to FIGS. 1 through 3.

Referring to FIG. 1, the substrate 110 provides a support unit of the electrode wires 140.

The substrate 110 may be formed of glass or film.

In this regard, the film may be formed of Polyethylene terephthalate (PET), Polycarbonates (PC), Poly(methyl methacrylate) (PMMA), Polyethylene naphthalate (PEN), Polyether sulfones (PES), Cyclic Olefin Copolymer (COC), Triacetyl Cellulose (TAC), Polyvinyl alcohol (PVA), Polyimide (PI), polystyrene (PS), biaxially oriented polystyrene BOPS; containing K resin), and so on, but the present invention is not limited thereto.

Meanwhile, high frequency processing or primer processing may be performed so as to activate both sides of the substrate 110. The both sides of the substrate 110 are activated, thereby enhancing a bonding force between the substrate 110 and the electrode wires 140.

Referring to FIGS. 1 through 3, the connection hole 120 is formed as one through one surface and another surface of the substrate 110.

The connection hole 120 provides a connection path of the electrode wirings 140 formed in one surface and another surface of the substrate 110.

In this regard, the connection hole 120 may be formed in, for example, a rectangular column ora cylinder.

Referring to FIGS. 1 through 3, the electrode wirings 140 include a plurality of first wirings 141 formed on one surface of the substrate 110, a plurality of second wirings 143 formed on another surface of the substrate 110, and a plurality of connection wirings 142 formed on an inner surface of the connection hole 120 and respectively electrically connecting the plurality of first wirings 141 and the plurality of second wirings 143.

Referring to FIGS. 2 and 3, the first wirings 141 and the second wirings 143 are arranged to be in disagreement with each other.

In this regard, the first wirings 141 and the second wirings 143 are arranged in parallel to each other while one side portion of the second wirings 143 is distorted so that the first wirings 141 and the second wirings 143 may not be consistent with each other in a horizontal direction or in a vertical direction. Accordingly, crosstalk between the first wirings 141 and the second wirings 143 may be reduced.

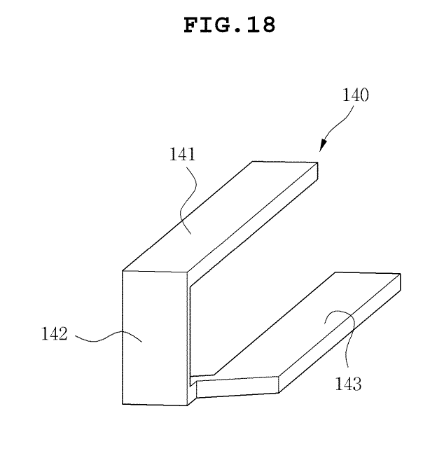

FIG. 18 is a perspective view of a main part of electrode wirings of the multilayer wiring structure 100 according to an embodiment of the present invention.

Referring to FIG. 18, the second wirings 143 are not formed in a plurality of layers but are formed in a single layer while one side of the second wirings 143 is distorted on the same plane.

As described above, the multilayer wiring structure 100 according to an embodiment of the present invention may enhance a wiring concentration by connecting the plurality of first wirings 141 and the plurality of second wirings 143 formed on one surface and another surface of the substrate 110 each other through the connection hole 120 formed in the substrate 110.

Also, operation time taken to form the connection hole 120 may be reduced, and an exchange cycle of a drill abraded during a drilling operation performed to form the connection hole 120 may be reduced, and thus exchange expense may be reduced.

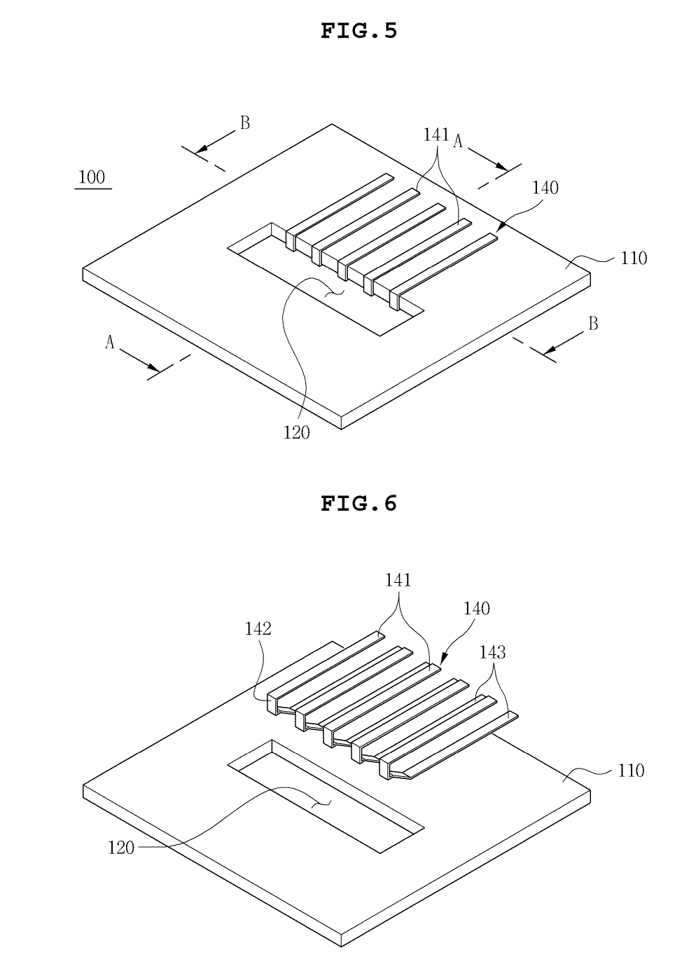

FIG. 4 is a flowchart of a method of manufacturing a multilayer wiring structure according to another embodiment of the present invention. FIG. 5 is a perspective view of a multilayer wiring structure manufactured by using a method of manufacturing the multilayer wiring structure according to another embodiment of the present invention. FIG. 6 is an exploded perspective view of a multilayer wiring structure manufactured by using a method of manufacturing the multilayer wiring structure according to another embodiment of the present invention.

Referring to FIGS. 4 through 6, the method of manufacturing a multilayer wiring structure according to another embodiment of the present invention includes a hole forming operation (S10) of forming the connection hole 120 through which one surface and another surface of the substrate 110 pass, a metal layer forming operation (S20) of plating a metal layer 130 on the substrate 110, a resist stacking operation (S30) of stacking resist on the metal layer 130, and an electrode wirings forming operation (S40) of forming the electrode wirings 140 by forming the metal layer 130 in a pattern.

The method of manufacturing the multilayer wiring structure according to another embodiment of the present invention relates to a method of manufacturing the multilayer wiring structure 100 according to an embodiment of the present invention, and thus the same reference numerals are used to designate the same components.

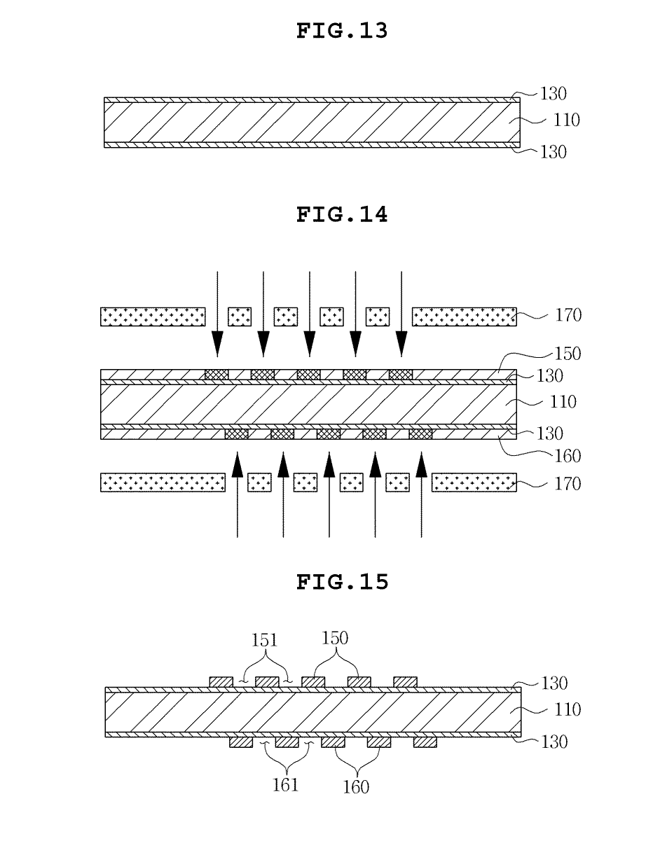

The method of manufacturing the multilayer wiring structure that is another embodiment of the present invention will now be described in more detail with reference to FIGS. 4 through 17.

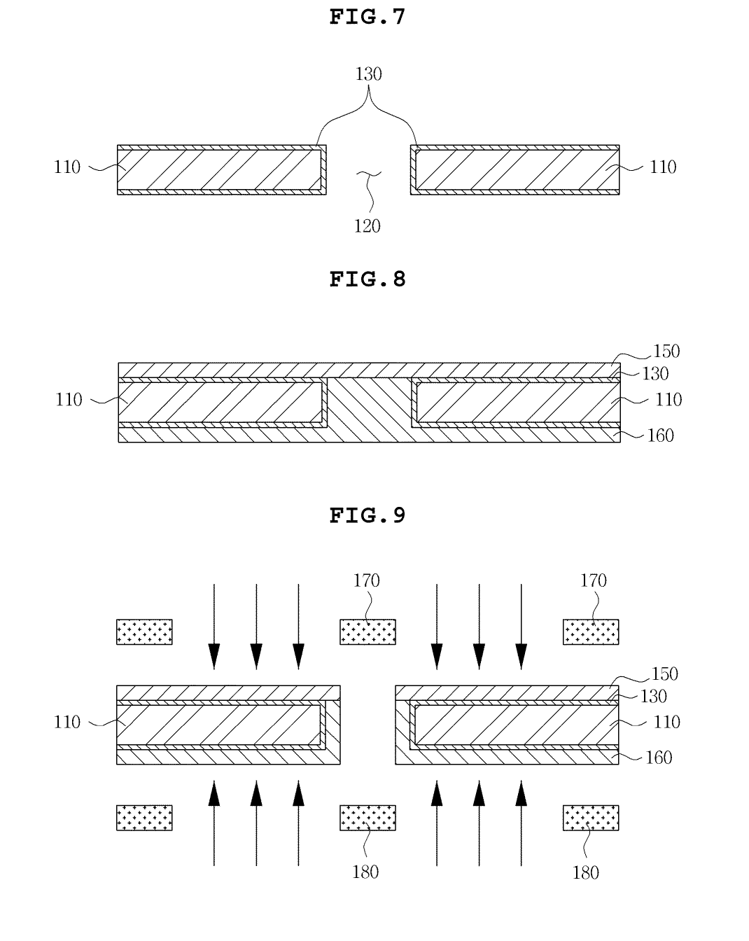

Referring to FIG. 7, the hole forming operation (S10) forms the connection hole 120 through which one surface and another surface of the substrate 110 pass.

In this regard, the connection hole 120 is formed by performing a drilling operation on the substrate 110 by using a tool such as a drill.

Also, the connection hole 120 may be formed in a rectangular column or a cylinder, but a shape of the connection hole 120 according to another embodiment of the present invention is not necessarily limited thereto.

In addition, the connection hole 120 provides a connection path of the electrode wirings 140 formed in one surface and another surface of the substrate 110.

Meanwhile, the substrate 110 may be formed of one of glass, film, or copper clad laminate (CCL), but a material of the substrate 110 according to another embodiment of the present invention is not necessarily limited thereto.

Referring to FIG. 7, the metal layer forming operation (S20) plates the metal layer 130 on one surface and another surface of the substrate 110 and inner surface of the connection hole 120.

In this regard, the metal layer 130 may be formed of one or more materials of copper (Cu), aluminum (Al), gold (Au), silver (Ag), titanium (Ti), palladium (Pd), chromium (Cr), chromium oxide (Cr2O3), chromium nitride (CrN), and chromium carbide (Cr3C2) but the present invention is not necessarily limited thereto.

Referring to FIG. 8, the resist stacking operation (S30) stacks a first resist 150 and a second resist 160 on the metal layer 130 formed in both sides of the substrate 110. In this regard, the resist stacking operation (S30) includes a resist forming operation, a curing operation, and a removing operation.

In this regard, referring to FIGS. 8 and 14, the resist forming operation stacks the first resist 150 on one surface of the substrate 110, and the second resist 160 on another surface of the substrate 110. At this time, the first resist 150 is formed of a dry film, and the second resist 160 is formed of a liquid resist.

In addition, referring to FIGS. 9 and 14, the curing operation selectively cures the first resist 150 and the second resist 160 by selectively exposing the first resist 150 and the second resist 160 through patterned photomasks 170 and 180.

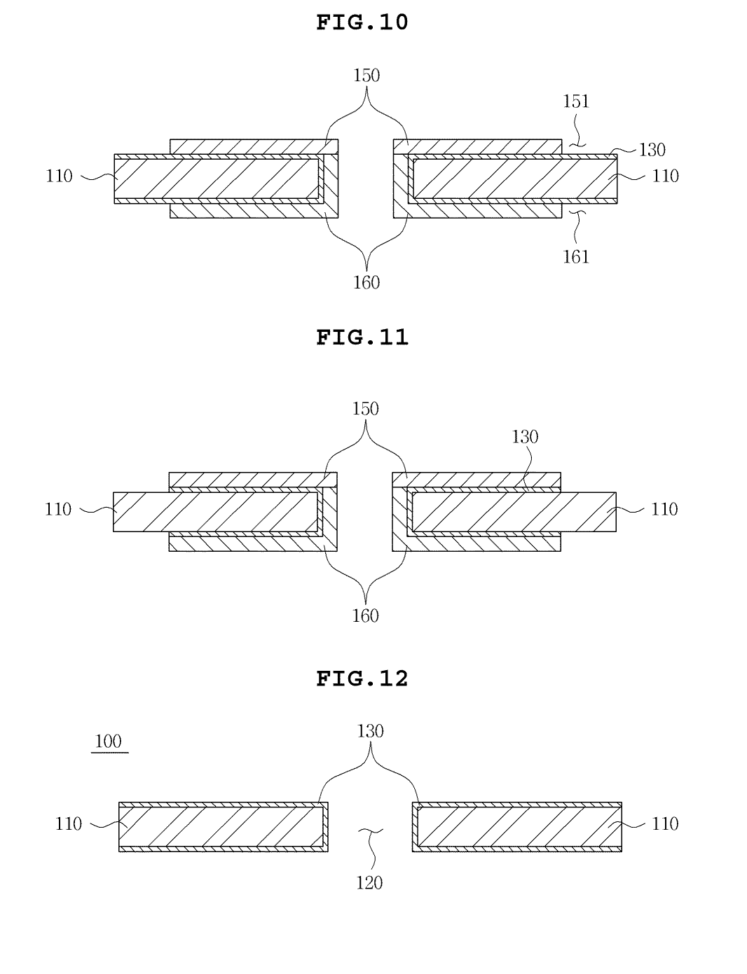

Referring to FIGS. 10 and 15, the removing operation provides the first resist 150 and the second resist 160 patterned by removing parts of the first resist 150 and the second resist 160 that are not cured by using a developing liquid.

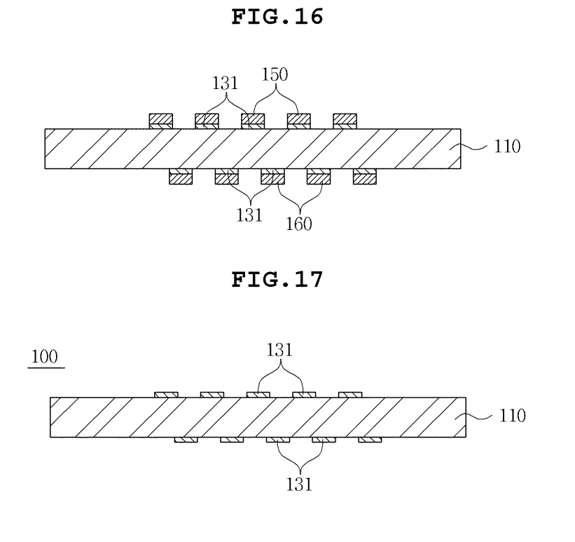

Referring to FIGS. 11 and 16, the electrode wirings forming operation (S40) forms the electrode wirings 140 patterned by etching the metal layer 130 through the first resist 150 and the second resist 160.

In this regard, the metal layer 130 is patterned by selectively coating an etching liquid on the metal layer 130 through openings 151 and 161 of the first resist 150 and the second resist 160 and selectively removing the metal layer 130. Thus, the electrode wirings 140 that are integrally formed through one surface and another surface of the substrate 110 and inner surface of the connection hole 120 and patterned may be provided. In this regard, the first wiring 141 are formed in plural on one surface of the substrate 110 and the second wirings 143 are formed in plural on another surface of the substrate 110, and the connection wirings 142 are formed on the inner surface of the connection hole 120 to respectively electrically connect the plurality of first wirings 141 and the plurality of second wirings 143.

However, the method of forming the electrode wirings 140 according to another embodiment of the present invention is not limited thereto. For example, the patterned electrode wirings 140 may be provided by selectively plating the metal layer 130 with a metal material through the openings 151 and 161 of the first resist 150 and the second resist 160, removing the first resist 150 and the second resist 160, and pouring the etching liquid to reduce a thickness of the metal layer 130.

In this regard, the metal material may be formed of one or more materials of copper (Cu), aluminum (Al), gold (Au), silver (Ag), titanium (Ti), palladium (Pd), chromium (Cr), chromium oxide (Cr2O3), chromium nitride (CrN), and chromium carbide (Cr3C2).

Referring to FIGS. 12 and 17, the electrode wirings forming operation (S40) may further include a resist removing operation of removing the first resist 150 and the second resist 160 stacked on the metal layer 130.

FIG. 18 is a perspective view of a main part of electrode wirings in a method of manufacturing the multilayer wiring structure according to another embodiment of the present invention.

Referring to FIG. 6, the first wirings 141 and the second wirings 143 may be formed to be in disagreement with each other.

In this regard, the first wirings 141 and the second wirings 143 are arranged in parallel to each other while one side portion of the second wirings 143 is distorted so that the first wirings 141 and the second wirings 143 may not be consistent with each other in a horizontal direction or in a vertical direction. Accordingly, crosstalk between the first wirings 141 and the second wirings 143 may be reduced.

In this regard, referring to FIG. 18, the second wirings 143 are not formed in a plurality of layers but are formed in a single layer while one side of the second wirings 143 is distorted.

According to the present invention, a plurality of wirings formed on a substrate in a plurality of layers are connected to each other through a single connection hole, thereby reducing a hole peeling failure that occurs when a plurality of holes are formed, and enhancing a wiring concentration. Further, an exchange cycle of a drill abraded during a drilling operation performed to form the plurality of holes may be reduced, and time taken to form the connection hole may be reduced.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A multilayer wiring structure comprising:
a substrate;
a connection hole formed to pass through one surface and another surface of the substrate; and
electrode wirings formed on the substrate,
wherein the electrode wirings include:
a plurality of first wirings formed on one surface of the substrate;
a plurality of second wirings formed on another surface of the substrate; and
a plurality of connection wirings formed on an inner surface of the connection hole and electrically connecting the plurality of first wirings and the plurality of second wirings, respectively.

2. The multilayer wiring structure as set forth in claim 1, wherein the plurality of first wirings and the plurality of second wirings are arranged to be in disagreement with each other.

3. A method of manufacturing a multilayer wiring structure, the method comprising:
a hole forming operation of forming a connection hole through which one surface and another surface of a substrate pass;
a metal layer forming operation of plating a metal layer on one surface and another surface of the substrate and an inner surface of the connection hole;
a resist stacking operation of stacking patterned first resist and second resist on the metal layer formed in both sides of the substrate respectively; and
an electrode wirings forming operation of forming the patterned electrode wirings by etching or plating the metal layer through the first resist and the second resist.

4. The method as set forth in claim 3, wherein the electrode wirings include:
a first wiring formed on one surface of the substrate;
a second wiring formed on another surface of the substrate; and
a connection wiring formed on an inner surface of the connection hole.

5. The method as set forth in claim 3, further comprising: after the patterning operation, a resist removing operation of separating the first resist and the second resist.

6. The method as set forth in claim 3, wherein, in the resist stacking operation, the first resist and the second resist are patterned and formed to be in disagreement with each other.

7. The method as set forth in claim 3, wherein, in the resist stacking operation, the first resist is formed of a dry film, and the second resist is a liquid resist, so that the connection hole is filled with the liquid resist.

8. The method as set forth in claim 7, wherein the resist stacking operation includes:
a resist forming operation of forming the first resist on one surface of the substrate and the second resist on another surface of the substrate;
a curing operation of selectively curing the dry film, and the liquid resist by selectively exposing the first resist and the second resist through patterned photomasks; and
removing operation of removing parts of the first resist and the second resist that are not cured by using a developing liquid.

9. The method as set forth in claim 8, wherein, in the resist forming operation, the first resist is formed of a dry film and coated on one surface of the substrate, and the second resist is a liquid resist and coated on another surface of the substrate.
